(19) United States
(12) Patent Application Publication
(10) Pub. No.: US 2008/0023732 A1
(43) Pub. Date: Jan. 31, 2008

(54) USE OF CARBON CO-IMPLANTATION WITH MILLISECOND ANNEAL TO PRODUCE ULTRA-SHALLOW JUNCTIONS

(76) Inventors: SUSAN B. FELCH, Los Altos, CA (US); Gregg S. Higashi, San Jose, CA (US)

Correspondence Address: PATTERSON & SHERIDAN, LLP, 3040 POST OAK BOULEVARD, SUITE 1500, HOUSTON, TX, 77056, US

(21) Appl. No.: 11/829,438

(22) Filed: Jul. 27, 2007

Related U.S. Application Data
(60) Provisional application No. 60/820,750, filed on Jul. 28, 2006.

(51) Int. Cl. H01L 29/94; H01L 21/425

(52) U.S. Cl. 257/288; 438/530; 257/E21.473; 257/E21.632

(57) ABSTRACT

Embodiments of the present invention include methods for forming an ultra-shallow junction in a substrate. In one embodiment, the method includes providing a silicon substrate, co-implanting the silicon substrate with carbon and a dopant to form a doped silicon substrate, and exposing the silicon substrate to a short time thermal anneal. In certain embodiments, the silicon substrate is exposed to a rapid thermal anneal after co-implanting the silicon substrate but prior to exposing the silicon substrate to a short time thermal anneal. In certain embodiments, the pre-amorphization implant is performed on the silicon substrate prior to implanting the silicon substrate with carbon and a dopant. In certain embodiments, the silicon substrate is a monocrystalline silicon substrate.

### CROSS-REFERENCE TO RELATED APPLICATIONS

This application claims benefit of U.S. Provisional Patent Application No. 60/820,750, filed Jul. 28, 2006, which is herein incorporated by reference.

### BACKGROUND OF THE INVENTION

1. Field of the Invention

Embodiments of the invention generally relate to the field of semiconductor manufacturing processes, and more particularly, to methods of forming ultrashallow junctions having reduced junction depths and improved dopant activation and profile abruptness.

2. Description of the Related Art

Integrated circuits may include more than one million micro-electronic field effect transistors (e.g., complementary metal-oxide-semiconductor (CMOS) field effect transistors) that are formed on a substrate (e.g., semiconductor wafer). A CMOS transistor includes a gate structure that is disposed between a source region and a drain region defined in the semiconductor substrate. The gate structure generally comprises a gate electrode formed on a gate dielectric material. The gate electrode controls a flow of charge carriers, beneath the gate dielectric, in a channel region that is formed between the drain region and the source region, so as to turn the transistor on or off. The drain and source regions are collectively referred to in the art as a “transistor junction”. There is a constant trend to reduce dimensions of the transistor junction in order to facilitate an increase in the operational speed of such transistors.

The CMOS transistor may be fabricated by defining source and drain regions in the semiconductor substrate using an ion implantation process. However, smaller dimensions for the transistors have necessitated the formation of source and drain regions with reduced depths (e.g., depths of between 100 Å to 500 Å). Such ultra shallow source/drain junctions are becoming more challenging to produce as junction depth is required to be less than 30 nm for sub-100 nm CMOS devices. Conventional doping by implantation followed by thermal post-annealing is less effective as the junction depth approaches the size of 10 nm, since thermal post-annealing can cause enhanced dopant diffusion. Dopant diffusion may contaminate nearby layers and cause failure of the device.

Therefore, there is a need for a method of forming ultrashallow junctions having reduced junction depths and improved dopant activation and profile abruptness.

### SUMMARY OF THE INVENTION

The present invention as recited in the claims relates to a method of forming an ultrashallow junction in a substrate. In one embodiment, the method includes providing a silicon substrate, co-implanting the silicon substrate with carbon and a dopant to form a doped silicon substrate, and exposing the silicon substrate to a short time thermal anneal. In certain embodiments, the silicon substrate is exposed to a rapid thermal anneal after co-implanting the silicon substrate but prior to exposing the silicon substrate to a short time thermal anneal. In certain embodiments, a pre-amorphization implant is performed on the silicon substrate prior to implanting the silicon substrate with carbon and a dopant. In certain embodiments, the silicon substrate is a monocrystalline silicon substrate.

In another embodiment a method of forming an ultra-shallow junction in a substrate is provided. The method includes providing a substrate comprising silicon with a gate dielectric and a gate electrode disposed thereon, performing a pre-amorphization implant of the substrate, co-implanting the substrate with carbon and a dopant to form a source region and a drain region on the substrate, exposing the substrate to a rapid thermal anneal, and exposing the substrate to a short time thermal anneal. In certain embodiments, an ultra-shallow junction is formed between the source region and the drain region having a junction depth less than 21 nm and an abruptness of ≦3 nm/decade.

In another embodiment, a structure having an ultra-shallow junction is provided. The structure comprises a microcrystalline silicon substrate, a source region and a drain region defined by ions co-implanted in the microcrystalline silicon substrate and activated by a short time anneal, and an ultra-shallow junction formed between the source region and the drain region on the substrate having a junction depth less than 21 nm. In certain embodiments, the ultra-shallow junction has an abruptness of ≦3 nm/decade.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and embodiments disclosed may be readily utilized as a basis for modifying or designing other structures or processes for carrying out the same purposes of the present invention. It should also be realized by those skilled in the art that such equivalent constructions do not depart form the spirit and scope of the invention as set forth in the appended claims.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A-1E depict a step-wise formation of layers within a gate stack structure;

FIG. 2 is a flow chart illustrating an exemplary process for forming an ultra-shallow junction on a substrate;

FIG. 3 depicts Secondary Ion Mass Spectrometry (SIMS) profiles of boron as-implanted with germanium pre-amorphization and after 1050° C. spike anneal with germanium pre-amorphization implant and fluorine or carbon co-implant;

FIG. 4 depicts Secondary Ion Mass Spectrometry (SIMS) profiles of phosphorous as-implanted and after 1050° C. spike anneal alone, with carbon co-implant, and with silicon pre-amorphization implant and carbon co-implant; and

FIG. 5 depicts a formed ultra-shallow junction in a source and drain region in a substrate.

### DETAILED DESCRIPTION

Embodiments of the present invention include methods for forming an ultrashallow junction in a substrate. Generally, the ultrashallow junction is formed by providing a silicon substrate. Optionally, a pre-amorphization implant step may be performed on the silicon substrate. The silicon substrate is co-implanted with carbon and a dopant to form a doped silicon substrate or layer. The substrate is exposed to a short time thermal anneal to activate the dopants. The substrate may also be exposed to a rapid thermal anneal prior to the short time thermal anneal.

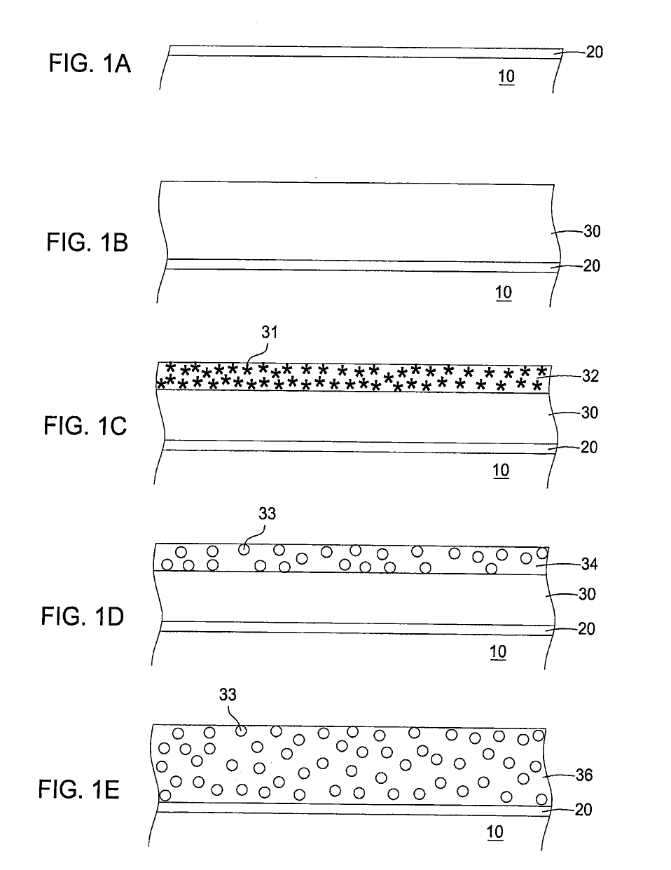

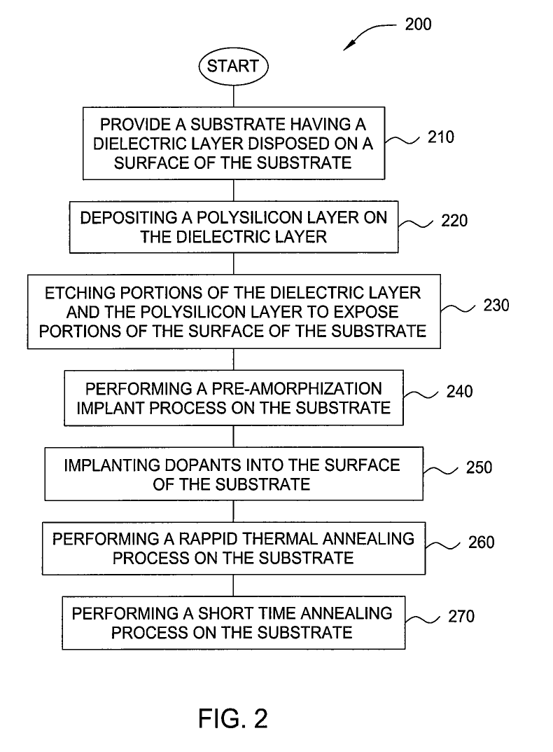

FIGS. 1A-1E show a cross-sectional view of a gate stack structure progressing through processes disclosed in one embodiment of the invention. FIG. 2 is a flow chart illustrating an exemplary process sequence 200 for forming an ultra-shallow junction on a substrate. In step 210, a substrate having a dielectric layer disposed on a surface of the substrate is provided. In step 220, a polysilicon layer is deposited on the dielectric layer. In step 230, portions of the dielectric layer and the polysilicon layer are etched to expose portions of the surface of the substrate. In step 240, a pre-amorphization implant (PAI) process is performed on the substrate. In step 250, the exposed portions of the surface of the substrate are co-implanted with carbon and a dopant. In step 260, a rapid thermal anneal is performed on the substrate. In step 270, a short time anneal of the substrate is performed.

The method begins at step 210 where a substrate 110 having a dielectric layer 120 disposed on a surface of the substrate 110 is provided, as shown in FIG. 1A. The substrate may contain monocrystalline surfaces and at least one secondary surface that is non-monocrystalline, such as polycrystalline or amorphous surfaces. Monocrystalline surfaces include the bare crystalline substrate or a deposited single crystal layer usually made from a material such as silicon, silicon germanium or silicon carbon. Polycrystalline or amorphous surfaces may include dielectric materials, such as oxides or nitrides, specifically silicon oxide or silicon nitride, as well as amorphous silicon surfaces. The substrate 110 may comprise a base layer (not shown) with a silicon layer disposed thereon which may be polycrystalline silicon, a doped or undoped polysilicon layer, or a crystalline silicon layer. In one example, the silicon layer may be a microcrystalline silicon layer. The base layer may be a material such as crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), doped silicon, germanium, gallium arsenide, glass, and sapphire. The base layer may have various dimensions, such as 200 mm or 300 mm diameter wafers, as well as, rectangular or square panes. In embodiments where the silicon layer is not present, the process steps may be performed directly on the base layer. The substrate 110 is usually pre-cleaned with a conventional pre-gate clean prior to the deposition of dielectric layer 120.

Dielectric layer 120 may be deposited onto substrate 110 by a variety of deposition processes, such as rapid thermal oxidation (RTO), chemical vapor deposition (CVD), plasma enhanced-CVD (PE-CVD), physical vapor deposition (PVD), atomic layer deposition (ALD), atomic layer epitaxy (ALE) or combinations thereof. Preferably, a dielectric material, such as SiO₂ or SiOₓN_{y}, is grown on the substrate 110 by an RTO process. Materials suitable as dielectric layer 120 include silicon oxide, silicon nitride, silicon oxynitride, hafnium oxide, hafnium silicate, aluminum oxide, aluminum silicate, zirconium oxide, zirconium silicate, derivatives thereof and combinations thereof. Generally, dielectric layer 120 is deposited with a thickness in a range from about 1 Å to about 150 Å, preferably from about 5 Å to about 50 Å.

In some embodiments, the dielectric material may be nitrided, such as with decoupled plasma nitridation (DPN) or thermal nitridation in nitric oxide (NO) or nitrous oxide (N₂O). A post-nitridation anneal is conducted to more strongly bond nitrogen into the oxide and to improve the interface between dielectric layer 120 and the substrate 110. For example, silicon oxide may be grown on the substrate 110 by an RTO process, followed by a DPN process to form a silicon oxynitride with a nitrogen concentration in a range from about 1×10¹⁴ atoms/cm² to about 1×10¹⁶ atoms/cm², for example, about 1×10¹⁵ atoms/cm². Other nitrided dielectric materials include aluminum oxynitride, nitrided hafnium silicate, hafnium oxynitride and zirconium oxynitride.

In step 220, a polysilicon layer 130, such as polycrystalline silicon, is deposited on the dielectric layer 120, as shown in FIG. 1B. Polysilicon layer 130 is generally deposited by chemical vapor deposition (CVD), rapid thermal-CVD (RT-CVD), plasma enhanced-CVD (PE-CVD), physical vapor deposition (PVD), atomic layer deposition (ALD), atomic layer epitaxy (ALE) or combinations thereof. Preferably, the polysilicon layer 130 is deposited with an RT-CVD process at a temperature in a range from about 650° C. to about 800° C., preferably from about 700° C. to about 750° C. During an RT-CVD process, the temperature may be varied to induce variances in grain size of the polysilicon layer 130. For example, the average polysilicon grain size may be about 50 Å larger at 720° C. than at 710° C. Generally, polysilicon layer 130 is deposited with a thickness in a range from about 100 Å to about 10,000 Å, preferably from about 500 Å to about 2,500 Å, and more preferably from about 750 Å to about 1,500 Å. Dual layer polysilicon may also be deposited with an RT-CVD process. Polysilicon layer 130 is generally polycrystalline silicon, but may contain other elements such as germanium and/or carbon. Therefore, polysilicon layer 130 may include Si, SiGe, SiC, or SiGeC. In some examples, the polysilicon layer may have a columnar structure with thin diameter or a dual layer structure combination including a microgram layer on the bottom and a columnar layer on the top.

Hardware that may be used to deposit dielectric layers and/or polysilicon layers include the Epi CENTURA® system and the POLYGEN® system available from Applied Materials, Inc., located in Santa Clara, Calif. A useful rapid-thermal CVD chamber for growing oxides is the Radiance® system available from Applied Materials, Inc., located in Santa Clara, Calif. An ALD apparatus that may be used to deposit high-k layers and/or polysilicon layers is disclosed in commonly assigned U.S. Ser. No. 10/032,284, filed Dec. 21, 2001, published as US 2003-0079686, and issued as U.S. Pat. No. 6,916,398, which is incorporated herein by reference in entirety for the purpose of describing the apparatus. Other apparatuses include batch, high-temperature furnaces, as known in the art.

In step 230, portions of the dielectric layer 120 and the polysilicon layer 130 are etched to expose portions of the surface of the substrate 110. As depicted in FIG. 1C opposed sidewall surfaces may be defined by etching portions of the dielectric layer 120 and the polysilicon layer 130 not covered by a patterned photoresist layer (not shown) using, for example, a directional plasma etching technique. As depicted in FIG. 1C, the dielectric layer 120 and the polysilicon layer 130 have been selectively etched to form gate dielectric 132 and polysilicon gate 134.

In step 240, optionally, in certain embodiments, the substrate 110 is subject to a PAI step prior to co-implantation of the substrate 110. PAI limits the depth to which implants can be made. Ions are implanted in a sufficient concentration to disrupt the crystal lattice structure of the substrate 110 so that it becomes amorphous. The PAI may be performed with a desired dopant, dose, and energy, and under a desired implant angle. Examples of dopants which may be used for PAI are Ge, Xe, Si, and Ar. Dose, energy, and angle may be selected according to requirements for the structure to be formed. For example, in the specific case of a Ge PAI, implantation may occur at 20 keV with 5*10e¹⁴ atoms/cm³ and under an angle between 0° and 45°. Furthermore, the choice of dopants depends on the semiconductor material used for the substrates.

In step 250, the exposed portions of the surface of the substrate are co-implanted with carbon and a dopant. FIG. 1D illustrates carbon and elemental dopants collectively referred to as 140 in an upper portion 142 of the substrate 110. The carbon and elemental dopants penetrate into the substrate 110 at a depth in a range from about a single atomic layer to about 500 Å, preferably about 150 Å. Elemental dopants may include boron, arsenic, phosphorus, gallium, antimony, indium, fluorine, or combinations thereof. Elemental dopants may have a concentration in the substrate 110 in a range from about 1×10¹⁹ atoms/cm³ to about 1×10²¹ atoms/cm³. In one example, the substrate 110 is doped P type, such as by co-implantation of carbon and boron to a concentration in the range from about 1×10¹⁹ atoms/cm³ to about 1×10²¹ atoms/cm³, preferably from about 1×10²⁰ atoms/cm³ to about 5×10²⁰ atoms/cm³. In another example, the upper portion 142 of the substrate 110 is doped N⁺ type, such as by co-implantation of carbon and phosphorus to a concentration in the range from about 1×10¹⁹ atoms/cm³ to about 1×10²¹ atoms/cm³, preferably from about 1×10²⁰ atoms/cm³ to about 5×10²⁰ atoms/cm³. In another example, the substrate 110 is doped N⁻ type by implanting carbon and diffusing arsenic or phosphorus to a concentration in the range from about 1×10¹⁹ atoms/cm³ to about 1×10²¹ atoms/cm³. In certain embodiments, the exposed portions of the surface of the substrate are co-implanted with fluorine and a dopant.

Dopants may be implanted with an ion implantation process, such as described in commonly assigned, U.S. Pat. No. 6,583,018, which is incorporated herein by reference in its entirety for the purpose of describing the apparatus. An ion implantation apparatus useful in embodiments of the invention is capable of planting ions with a very low implantation energy, such as about 5 KeV or less, preferably about 3 KeV or less. Two ion implantation apparatuses useful during embodiments of the invention are manufactured and sold as the QUANTUM X Plus system, the QUANTUM® III system, and the PRECISION IMPLANT 9500 XR® system, both available from Applied Materials, Inc., located in Santa Clara, Calif. Boron may be implanted with an energy setting of about 0.5 KeV and a dose setting in a range from about 1×10¹⁴ atoms/cm² to about 1×10¹⁶ atoms/cm². In one example, the boron is implanted at about 7×10¹⁴ atoms/cm². In another example, boron is implanted at about 1×10¹⁵ atoms/cm².

During step 260, the substrate 110 is exposed to a thermal anneal process to diffuse and distribute the carbon and elemental dopants 140 and the silicon within the substrate 110 to form an activated doped silicon layer 146 as shown in FIG. 1E. Atom sites within the crystalline lattice of the upper portion of the substrate 110 are replaced by carbon and dopant atoms collectively referred to as 144. Therefore, the crystalline lattice, usually silicon, opens and incorporates the incoming carbon and dopant atoms such as boron, arsenic, phosphorus, or other dopants described herein. The preferred annealing process is a rapid thermal annealing (RTA) process lasting in a range from about 1 second to about 20 seconds, preferably from about 1 second to about 2 seconds. During the RTA process, the substrate is heated to a temperature in a range from about 800° C. to about 1,400° C., preferably from about 950° C. to about 1,050° C. In one example of an RTA process, the substrate is heated to about 1,000° C. for about 5 seconds. The correct combination of temperature and time during the RTA process distributes carbon and dopant elements throughout the upper portion 142 of the substrate 110 without contaminating nearby features in the device. A process chamber used during RTA processes described herein is the CENTURA® RTP system, available from Applied Materials, Inc., located in Santa Clara, Calif.

In one embodiment, the thermal anneal process includes spike annealing. Spike annealing may be performed in an RTP system capable of maintaining gas pressure in the annealing ambient at a level significantly lower than the atmospheric pressure. An example of such an RTP system is the RADIANCE CENTURA® system commercially available from Applied Materials, Inc., Santa Clara, Calif. Spike annealing is further discussed in commonly assigned U.S. Pat. No. 6,897,131, issued May 24, 2005, entitled ADVANCES IN SPIKE ANNEAL PROCESSES FOR ULTRA SHALLOW JUNCTIONS and commonly assigned U.S. Pat. No. 6,803,297, issued Oct. 12, 2004 entitled OPTIMAL SPIKE ANNEAL AMBIENT, which are herein incorporated by reference to the extent they do not conflict with the current specification and claims.

During step 270, the substrate 110 is subjected to a “short term thermal anneal” or “millisecond anneal.” As used herein, “short term thermal anneal” refers to processes where the doped surface layer is heated to a desired temperature for a time of about 100 milliseconds or less and preferably for a time of about 10 milliseconds or less.

In one embodiment the “short term thermal anneal” includes laser annealing by a dynamic surface annealing (DSA) process. The activated doped silicon layer 146 is heated during the DSA process near the melting point without actually causing a liquid state. The activated doped silicon layer 146 is heated at a temperature in a range from about 1,000° C. to about 1,415° C., preferably from about 1,050° C. to about 1,400° C. Temperatures higher than the melting point of crystalline silicon (about 1,415° C.) are not desirable, since dopant diffusion is likely to cause contamination of other materials within the feature. A layer may be exposed to the substrate during the DSA process for less than about 500 milliseconds, preferably less than 100 milliseconds. The DSA process can be conducted on a DSA platform, available from Applied Materials, Inc., located Santa Clara, Calif. Generally, the laser emits light with a wavelength selected from 10.6 μm or 0.81 μm.

In another embodiment, a “short term thermal anneal” is implemented as a flash RTP process. The flash RTP process involves: (1) rapid heating of the substrate to an intermediate temperature, and (2) while the substrate is heated to the intermediate temperature, very rapid heating of the doped surface layer to a final temperature. The final temperature is higher than the intermediate temperature, and the time duration of the second step is less than the first time duration of the first step. By way of example, the first step of the flash RTP process may involve heating the substrate to an intermediate temperature range in a range of about 500° C. to about 900° C. for a time range of about 0.1 seconds to 10 seconds. The second step may involve heating the doped surface layer to a final temperature in a range of about 1000° C. to about 1410° C. and preferably in a range of about 0.1 milliseconds to 100 milliseconds and preferably for a time in a range of about 0.1 to about 10 milliseconds.

### EXAMPLES

The following non-limiting examples are provided to further illustrate embodiments of the invention. However, the examples are not intended to be all-inclusive and are not intended to limit the scope of the inventions described herein.

Blanket wafer and device experiments were carried out on 200 mm Si wafers. To form the ultra-shallow source/drain extension (SDE) with co-implants, a first step of Si or Ge PAI was used. This was followed by a C or F implant and finally a dopant implant. The dopant implants were B for PMOS extensions and P for NMOS extensions. On the device wafers, these extensions were implemented in a conventional transistor flow, primarily with polysilicon gates on SiON gate dielectric but with Ni Fully Silicided (FUSI) gates in some cases.

Dopant activation and damage annealing was done by a 1050° C. spike anneal unless noted otherwise, and often followed by a sub-melt laser anneal. The implants were carried out on an Applied Materials Quantum X Plus single-wafer high-current implant system, while the activation spike anneal was performed on an Applied Vantage Radiance Plus RTP system, both available from Applied Materials, Inc. of Santa Clara, Calif. The scanning laser annealing technique had maximum temperature dwell times of about one millisecond. Chemical profiles were measured by secondary ion mass spectrometry (SIMS) using an Atomika 4500 instrument with a 500 eV O₂ analyzing beam. Two-dimensional profiles of activated carrier concentration were also obtained on selected samples by scanning spreading resistance microscopy (SSRM).

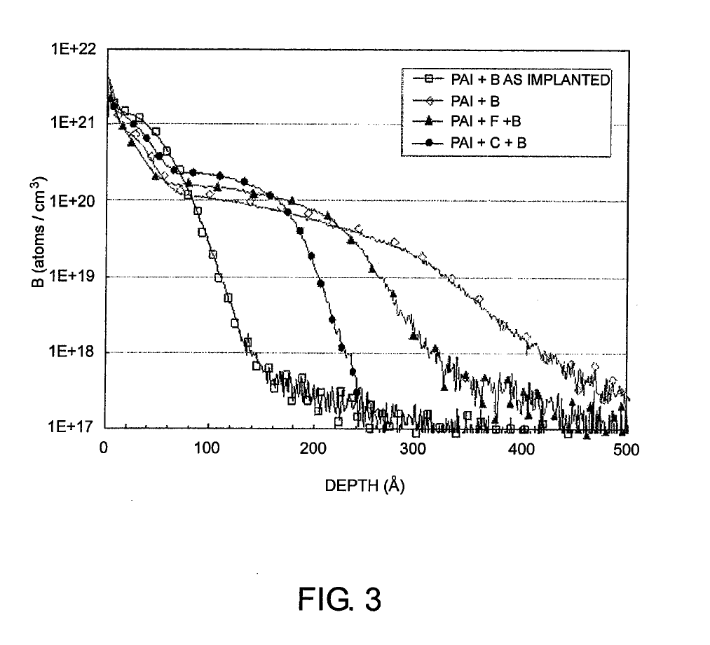

FIG. 3 depicts Secondary Ion Mass Spectrometry (SIMS) profiles of boron as-implanted with germanium pre-amorphization and after 1050° C. spike anneal with Ge PAI and F or C co-implant. FIG. 3 demonstrates the benefits of combining Ge pre-amorphization and F or C co-implantation with 500 eV, 1×10¹⁵ cm⁻² B implants. The Ge implant energies ranged from 2 to 20 keV, while the F was implanted at 10 keV and the C was implanted at 4 keV. Without F or C co-implant, the boron diffuses considerably during the 1050° C. spike anneal and produces a junction deeper than 40 nm at a concentration of 1×10¹⁸ cm⁻³ with a diffusion shoulder at a concentration of about 1×10²⁰ cm⁻³ and a sheet resistance of about 430 ohms/sq. The addition of co-implanted F significantly reduces the boron diffusion and creates a more box-like profile. The junction depth is only 30 nm, the profile abruptness is improved to 4.4 nm/decade, and the diffusion shoulder (which is indicative of the electrical activation) is increased to give a similar sheet resistance of 419 ohms/sq. in spite of the reduced junction depth. Nevertheless, the effect of co-implanted C is especially striking, as the B profile is now much steeper and considerably less diffused due to the trapping of Si interstitials by substitutional C. The junction depth has now been reduced to 23 nm, the abruptness is only 2.5 nm/decade, and the concentration of the diffusion shoulder has increased to 2×10²⁰ cm⁻³ so that the sheet resistance is only slightly increased to 573 ohms/sq.

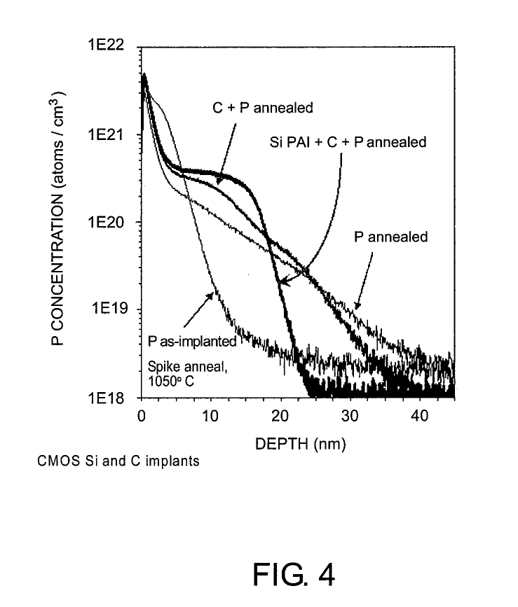

FIG. 4 depicts Secondary Ion Mass Spectrometry (SIMS) profiles of phosphorous as-implanted and after 1050° C. spike anneal alone, with C co-implant, and with Si PAI and C co-implant. Similar to the improvements seen with C co-implant for B dopant profiles, FIG. 4 presents the implementation of the same concept for the case of the n-type dopant P. A P-only implant with an energy of 1 keV and dose of 7×10¹⁴ cm⁻² activated by a 1050° C. spike anneal has a very long diffusion tail due to transient enhanced diffusion (TED), a relatively high junction depth of 35 nm at a concentration of 5×10¹⁸ cm⁻³, and a moderate sheet resistance of 411 ohms/sq. When a 6 keV, 1×10¹⁵ cm⁻² C co-implant is added with no pre-amorphization, the dopant activation (indicated by the P diffusion shoulder), sheet resistance (349 ohms/sq.), and profile abruptness are improved, and the junction depth is slightly reduced to 30 nm. Nevertheless, the Si+C+P case with an additional 25 keV, 1×10¹⁵ cm⁻² Si pre-amorphizing implant, which results in an initial amorphous layer of around 60 nm, shows a dramatically different profile. Here, the combination of a localized end-of-range (EOR) damage region coupled with a layer of substitutional C suppresses the interstitial-driven diffusion and very strongly impacts the shape of the P profile, producing a box of 21 nm depth with an abruptness of 3 nm/decade. The P diffusion shoulder occurs at a high concentration of 4×10²⁰ cm⁻³, resulting in an excellent conduction layer with a low sheet resistance of 318 ohms/sq.

Analysis of the device impact of F and C co-implants for the B source/drain extension profiles was also performed. The co-implanted junctions were activated with a spike anneal followed by an additional sub-melt laser anneal, while the BF₂ (1 keV, 1×10¹⁵ cm⁻²) reference junction was only activated with spike anneal. Two spike anneal temperatures (1050° C. and 1030° C.) and two laser anneal temperatures (1100° C. and 1300° C.) were investigated. The blanket wafer results showed improved dopant activation with F co-implant but a reasonably deep junction. Correspondingly, the F co-implanted junctions lead to lower S/D resistance, but the minimum gate length supported at fixed I_{off} is larger than that for the BF₂ conventional case. In contrast, C co-implanted junctions, which are much shallower and have greater dopant activation, produce improvements both in short channel effects and S/D resistance. Higher laser anneal temperature also provides further reduction in S/D resistance, suggesting that a high temperature, “diffusion-less” anneal after a spike anneal results in enhanced dopant activation.

The correlation between saturation on-state current corresponding to an off-state current of 60 nA and overlap capacitance (Cₒᵥ) for BF₂ implants and F and C co-implants at various spike anneal temperatures was also examined. The lower spike anneal temperature of 1030° C. leads to less lateral diffusion and smaller overlap capacitance for both F and C co-implants. In addition, the slightly deeper junction obtained with 1050° C. anneal increases Iₒₙ due to lower S/D resistance. F co-implant produces higher Iₒₙ without any reduction in Cₒᵥ, which is consistent with the improved dopant activation and fairly deep junctions seen on blanket wafers. However, 10% Iₒₙ gain is obtained with slightly reduced overlap capacitance for C co-implant and 1050° C. spike anneal, while a large reduction in Cₒᵥ accompanied by a small increase in Iₒₙ is achieved with 1030° C. anneal. These results highlight the suppression of lateral boron diffusion under the gate and the simultaneous improvement in the S/D resistance by the use of C co-implants.

A comparison of two-dimensional SSRM images of activated carrier concentration for a BF₂ implanted device and a C co-implanted device after spike anneal demonstrates the ability of C co-implant to reduce the boron vertical diffusion. The SDE vertical junction depth is dramatically reduced from 38 nm to 14 nm and even the HDD junction depth is decreased from 90 nm to 82 nm. In addition, C co-implant strongly suppresses the boron lateral diffusion such that the gate/SDE overlap is shrunk from 22 nm to 10 nm, which is consistent with the electrically measured reduction in Cₒᵥ.

Dopant activation by sub-melt laser annealing without any spike anneal is attractive due to the high dopant activation levels achieved with minimal diffusion. In order to compare the device performance of laser anneal with a reference spike anneal, the SDE implant energies for laser anneal are typically increased to compensate for the lack of diffusion and produce the same junction depth obtained with spike anneal. A 35% improvement in the S/D resistance is observed for the same overlap capacitance and 1300° C. anneal, which is consistent with improved dopant activation for the same lateral junction depth. Furthermore, the lowest resistance and highest dopant activation is reached for the maximum laser anneal temperature, following the trend with anneal temperature that has been observed on blanket wafers. Finally, Cₒᵥ values smaller than the reference value can be obtained with laser anneal, showing that the minimal diffusion with laser anneal can lead to reduced lateral junction depths. Analysis of a SSRM image of a laser-annealed device confirms that the lateral boron diffusion of both the SDE and HDD is greatly reduced with laser anneal, reinforcing the potential of laser anneal for dopant activation in sub-45 nm devices.

Blanket and device wafer studies have been conducted to verify the benefits of ultra-shallow junctions formed by co-implantation with conventional spike anneal and for sub-melt laser annealing. C co-implant improves the junction depth, profile abruptness concentration of the diffusion shoulder (which is indicative of the dopant activation) for both PMOS and NMOS. Devices with C co-implanted SDEs exhibit better short channel effects and S/D resistance, especially when a laser anneal is added after the spike anneal. Dopant activation by sub-melt laser annealing without any spike anneal produces improvement in the S/D resistance or reduced lateral junction depths and overlap capacitance. Finally, SSRM images confirm that the lateral boron diffusion of both the SDE and HDD is greatly reduced with co-implant or laser anneal.

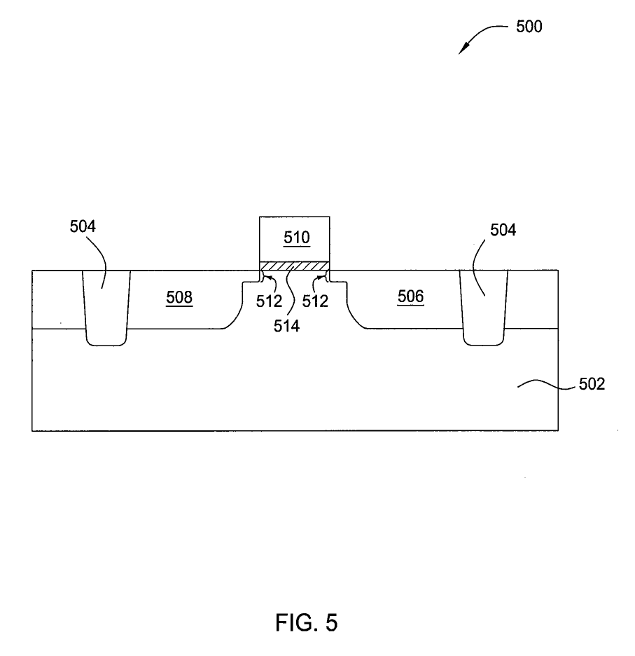

FIG. 5 depicts a formed ultra-shallow junction in a source and drain region in a substrate. The substrate 502 has at least one partially formed semiconductor device 500 disposed thereon. Shallow trench isolations (STI) 504 are present to isolate each semiconductor device 500 formed on the substrate 502. One device 500 and two STI's 504 are shown in FIG. 5. A polysilicon gate electrode 510 is formed on a gate dielectric layer 514 disposed on the substrate 502. Source 508 and drain 506 regions are formed adjacent the gate dielectric 514 in the substrate 502 by ion implantation with the dopants as discussed above. As the process described herein is performed on the substrate 502 the source 508 and drain 506 regions with the implanted dopants provides a desired ultra shallow junction with a minimum depth 512 less than about 21 nm with an abruptness of about 3 nm/decade.

While the foregoing is directed to embodiments of the present invention, other and further embodiments of the invention may be devised without departing from the basic scope thereof, and the scope thereof is determined by the claims that follow.

1. A method of forming an ultrashallow junction on a substrate, comprising:
providing a silicon substrate;
co-implanting the silicon substrate with carbon and a dopant to form a doped silicon substrate; and
exposing the silicon substrate to a short time thermal anneal.

2. The method of claim 1, further comprising:
exposing the silicon substrate to a rapid thermal anneal after co-implanting the silicon substrate but prior to exposing the silicon substrate to a short term thermal anneal.

3. The method of claim 1, further comprising:
performing a pre-amorphization implant on the silicon substrate prior to implanting the silicon substrate with carbon and a dopant.

4. The method of claim 3, wherein the performing a pre-amorphization implant comprises implanting germanium or silicon into the silicon substrate.

5. The method of claim 1, wherein the short term thermal anneal comprises a laser anneal.

6. The method of claim 5, wherein the laser anneal lasts for about 100 milliseconds or less.

7. The method of claim 1, wherein the dopant is selected from the group consisting of phosphorous, boron, arsenic, and combinations thereof.

8. The method of claim 1, wherein the silicon substrate comprises microcrystalline silicon.

9. A method of forming an ultrashallow junction in a substrate, comprising:
providing a substrate comprising silicon, a gate dielectric, and a gate electrode disposed thereon;
performing a pre-amorphization implant of the substrate;
co-implanting the substrate with carbon and a dopant to form a source region and a drain region on the substrate; and
exposing the substrate to a short time thermal anneal.

10. The method of claim 9, wherein the short term thermal anneal comprises a laser anneal.

11. The method of claim 10, wherein the laser anneal lasts for about 100 milliseconds or less.

12. The method of claim 9, wherein the dopant is selected from the group consisting of phosphorous, boron, arsenic, and combinations thereof.

13. The method of claim 9, wherein the performing a pre-amorphization implant comprises implanting germanium or silicon into the substrate.

14. The method of claim 9, further comprising exposing the substrate to a rapid thermal anneal to activate the source and drain region prior to exposing the substrate to a short time thermal anneal.

15. The method of claim 9, wherein the substrate comprises microcrystalline silicon.

16. The method of claim 9, wherein the short time anneal comprises a flash RTP process.

17. The method of claim 9, wherein the rapid thermal anneal comprises a spike anneal.

18. The method of claim 9, further comprising forming an ultra shallow junction between the source region and the drain region having a junction depth less than 21 nm and an abruptness of 3 nm/decade.

19. A structure having an ultra-shallow junction, the structure comprising:
a semiconductor substrate comprising microcrystalline silicon;
a source region and a drain region defined by ions co-implanted in the substrate and activated by a short time anneal; and
an ultra-shallow junction formed between the source region and the drain region on the substrate having a junction depth less than 21 nm.

20. The structure of claim 19, wherein the ultra-shallow junction has an abruptness of 3 nm/decade.
